(19) United States
(12) Patent Application Publication
(10) Pub. No.: US 2015/0303866 A1
(43) Pub. Date: Oct. 22, 2015

(54) CONCENTRATING SOLAR CELL MODULE PANEL HAVING STIFFNESS AND CONCENTRATING PHOTOVOLTAIC GENERATION SYSTEM COMPRISING SAME

(71) Applicant: ANYCASTING CO., LTD., Seoul (KR)

(72) Inventors: Sungbin KIM, Goyang-si, Gyeonggi-do (KR); Jangkyun KIM, Bucheon-si, Gyeonggi-do (KR); Byungwook KIM, Incheon-si (KR); Chankyu PARK, Seoul (KR)

(21) Appl. No.: 14/437,833

(22) PCT Filed: Oct. 25, 2012
(86) PCT No.: PCT/KR2012/008829

§ 371 Date: Apr. 23, 2015

(30) Foreign Application Priority Data
Oct. 25, 2012 (KR) 10-2012-0119212

(51) Int. Cl. H02S 30/10; H02S 40/42; H01L 31/054

(52) U.S. Cl. CPC H02S 30/10; H01L 31/0543; H02S 40/425

(57) ABSTRACT

Disclosed is a concentrated photovoltaic module including a heat pipe. The concentrated photovoltaic module includes: a frame that is configured to have a side surface plate and a lower plate; a carrier which is provided with the solar cell; a lens plate that is provided on the frame to concentrate incident light into the solar cell; a carrier frame that is provided on the lower plate, a plurality of the carriers being provided thereon at predetermined intervals; a wire which connects the carriers with each other; and a wire cover that is provided in the lower plate to cover the wire and is coupled with the lower plate in a state in which the carrier frame is fixed.

### TECHNICAL FIELD

The present invention relates to a concentrating photovoltaic module including a heat pipe, and more particularly, to a concentrating photovoltaic module for easily integrally assembling a heat pipe for dissipating heat generated from a solar cell with a concentrating photovoltaic module that has comparatively high stiffness and is configured such that manufacture and assembly thereof are facilitated. This application claims the benefit of Korean Patent Application No. 10-2012-0119212, filed on Oct. 25, 2012, which is hereby incorporated by reference in its entirety into this application.

### BACKGROUND ART

Recently, photovoltaic (PV) apparatuses using solar light been widely used. Particularly, photovoltaic apparatuses using silicon solar cells are mainly used.

By virtue of rapid process in technology pertaining to high efficiency III-V compound semiconductor multi junction solar cells in recent years, researches have been actively conducted on concentrating photovoltaic (CPV) apparatuses using a method of concentrating solar light on multi junction solar cells through inexpensive devices.

Multi-junction solar cells have high energy conversion efficiency compared to that of silicon solar cells. Generally, multi junction solar cells have an energy efficiency of more the 35% while silicon solar cells have an energy efficiency of approximately 20%. Specially, under conditions of light concentration, some multi junction solar cells have energy efficiency of more the 40%.

A concentrating solar cell module using such multi junction solar cells includes solar cells, a primary lens for primarily concentrating solar light, and a secondary lens for secondarily concentrating on the solar cells the solar light concentrated by the primary lens. The solar cells are mounted to a cell mount such as a circuit board, or a receiver, for example, disclosed in Korean Patent Unexamined Publication No. 10-2010-0135200.

Concentrating photovoltaic generation systems are configured in such a way that a plurality of concentrating solar cell modules are provided in an array form on a support frame. Furthermore, the concentrating photovoltaic generation systems include a tracking device for rotating the solar cell module array such that the solar cell modules may be maintained to be perpendicular to the sun, thus enhancing the efficiency of the multi-junction solar cells.

A representative example of such a concentrating photovoltaic generation system is disclosed in Korean Patent Registration No. 10-1003539 (hereinafter, referred to as a ‘prior art 1’), entitled “Ground solar cell array.”

The prior art 1 relates to a solar cell array using III-V compound semiconductor solar cells. As shown in FIGS. 1 and 2, a concentrating photovoltaic generation system according to the prior art 1 includes a center support 1, a support frame 2, a plurality of solar cell sub-arrays or panels 3, and an actuator for rotating the center support 1 and the support frame 2 such that the solar cell array may be maintained to be perpendicular to the rays of the sun. The sub-arrays or panels 3 are formed by stacking modules 4 on top of each other.

However, as shown in FIG. 2, according to the prior art 1, the sub-arrays or panels 3 are formed by stacking the modules 4 on top of each another, and thus it is not easy to manufacture and assembly the sub-arrays or panels 3 and a drooping phenomenon of modules 5 disposed outside of the support frame 2 occurs due to their own weight. Accordingly, there is a problem in that some of the modules 5 are not perpendicular to the rays of the sun even if the actuator rotates the support frame 2.

Although not disclosed in the prior art 1, in order to overcome the above problem, there is a need for a separate frame structure for preventing the modules disposed outside of the support frame 2 from drooping on the sub-arrays or panels 3 including the modules 4. Furthermore, as shown in FIG. 1, the support frame 2 supporting the horizontally-arranged panels 3 has a structure that is inevitably complex due to a requirement to maintain the stiffness of the panels 3. Accordingly, the overall construction of the concentrating photovoltaic generation system is complex and the weight of the system also increases, thus causing the load applied to the actuator to be increased. Accordingly, an actuator having a comparatively large capacity is required, thereby increasing manufacturing costs of the system.

The efficiency of III-V compound semiconductor solar cells that are mainly used for concentrating photovoltaic modules is remarkably degraded by heat, and in general, concentrating photovoltaic modules include a heat dissipation device for dissipation of heat generated from the solar cell.

Korean Patent Unexamined Publication No. 10-2010-0083945 (hereinafter, referred to as a ‘prior art 2’) discloses a “heat dissipation module of high-concentrating photovoltaic apparatus”. However, the dissipation module according to the prior art 2 includes a heat dissipation pin that protrudes upwards and downward, and thus there is a problem in that the volume of the module increases and the heat dissipation module needs to be separately assembled to the high-concentrating photovoltaic apparatus.

In addition, Korean Patent Unexamined Publication No. 10-2011-0036221 (hereinafter, referred to as a ‘prior art 3’) discloses a “photovoltaic generation apparatus” including a heat pipe. However, there is a problem in that the photovoltaic generation apparatus according to the prior art 3 has a complex structure for installing the heat pipe.

### DISCLOSURE

### Technical Problem

Accordingly, the present invention has been made keeping in mind the above problems occurring in the prior art, and an object of the present invention is to provide a concentrating solar cell module that has comparatively high stiffness and is configured such that manufacture and assembly thereof may be facilitated.

### Technical Solution

The object of the present invention may be achieved by providing a concentrating photovoltaic module including a frame including a side plate and a lower plate, carriers each provided with a solar cell, a lens plate disposed on the frame and for concentrating sunlight incident thereon on the solar cell, a carrier frame disposed on the lower frame and including the plurality of carriers spaced apart from each other by a predetermined interval, a wire for connection of the carriers, and a wire cover disposed to cover wire and coupled to the lower plate while fixing the carrier frame.

The carrier frame may include a heat pipe disposed therein. In addition, the carrier frame may extend in a longitudinal direction, the carriers may be arranged in a longitudinal direction to be spaced apart from each other in a line by a predetermined interval on the carrier frame, and heat dissipation ribs may protrude below the lower plate.

The wire cover may include an upper plate for covering the wire, a first leg portion extending downward from one side of the upper plate and coupled to the lower plate, and a second leg portion extending downward from another side of the upper plate so as to be positioned inside the first leg portion and for compressing the carrier frame when the first leg portion is coupled to the lower plate.

The second leg portion may be formed with a shorter length than that of the first leg portion or inclined at a predetermined angle, or one pair of second leg portions may face each other and is formed to be away from each other downward.

A stumbling portion stumbled by a stumbling projection formed on the lower plate may be formed at one side of the first leg portion. The concentrating photovoltaic module may further include a secondary optical element for secondarily concentrating light concentrated from the lens plate on the solar cell, wherein the wire cover may further include a third leg portion for compressing a flange of the secondary optical element when the first leg portion extends downward from one side of the upper plate and is coupled to the lower plate.

The side plate may include a horizontal plate and a vertical plate extending a greater length than the horizontal plate, the lower plate may include a plurality of lower plate pieces arranged and coupled in a vertical direction and each coupled to the vertical plate by screws, and the carrier frame may extend in a longitudinal direction of the lower plate pieces, the carriers are arranged in the longitudinal direction to be spaced apart from each other in a line on the carrier frame, and heat dissipation ribs protrude below the lower plate pieces, and a heat pipe may be disposed in the carrier frame.

The side plate may include a horizontal plate and a vertical plate extending a greater length than the horizontal plate, the lower plate may include a plurality of lower plate pieces arranged and coupled in a vertical direction and each coupled to the vertical plate by screws, the lower plate pieces may include heat dissipation ribs protruding therebelow and an accommodation portion extending thereabove in a longitudinal direction and for accommodation the carrier frame, the carrier frame may extend in a longitudinal direction of the lower plate pieces, an accommodation groove may extend in a longitudinal direction on the carrier frame such that the carriers are arranged to be spaced apart from each other in a line by a predetermined interval, and a heat pipe may be disposed in the carrier frame.

### Advantageous Effects

A concentrating photovoltaic module having the aforementioned configuration according to embodiments of the present invention may include a heat pipe for dissipating heat generated from a solar cell, disposed in a carrier frame to be easily and integrally assembled with a lower plate of a frame configured with comparatively high stiffness so as to easily and integrally assemble the heat pipe with a photovoltaic module.

The concentrating photovoltaic module according to embodiments of the present invention may be configured in such a way that a heat pipe 62 is disposed in a carrier frame coupled onto a lower plate so as to directly contact the lower plate in a longitudinal direction of the lower plate and including carriers arranged in the longitudinal direction of the lower plate, thereby maximizing an effect of heat dissipation.

The concentrating photovoltaic module according to embodiments of the present invention may be configured in such a way that a wire cover for covering a wire is coupled to the lower plate while fixing the carrier frame, and thus does not require a separate configuration for fixing the carrier frame to the lower plate, thereby simplifying an overall structure and assembling procedures.

### DESCRIPTION OF DRAWINGS

FIGS. 1 and 2 are diagrams illustrating a concentrating photovoltaic generation system according to a prior art.

FIG. 3 is a perspective view of a concentrating photovoltaic module according to an embodiment of the present invention.

FIG. 4 is a vertical cross-sectional view of the concentrating photovoltaic module of FIG. 3 taken along a horizontal line thereof.

FIG. 5 is a vertical cross-sectional view of the concentrating photovoltaic module of FIG. 3 taken along a vertical line thereof.

FIG. 6 is a schematic diagram of a case in which carriers are arranged on a lower plate of a concentrating photovoltaic module according to an embodiment of the present invention.

FIG. 7 is an enlarged view of a portion ‘A’ of FIG. 4.

FIG. 8 is an enlarged view of a portion ‘B’ of FIG. 5.

FIG. 9 is a perspective view of a wire cover according to an embodiment of the present invention.

FIG. 10 is a perspective view of a carrier frame according to an embodiment of the present invention.

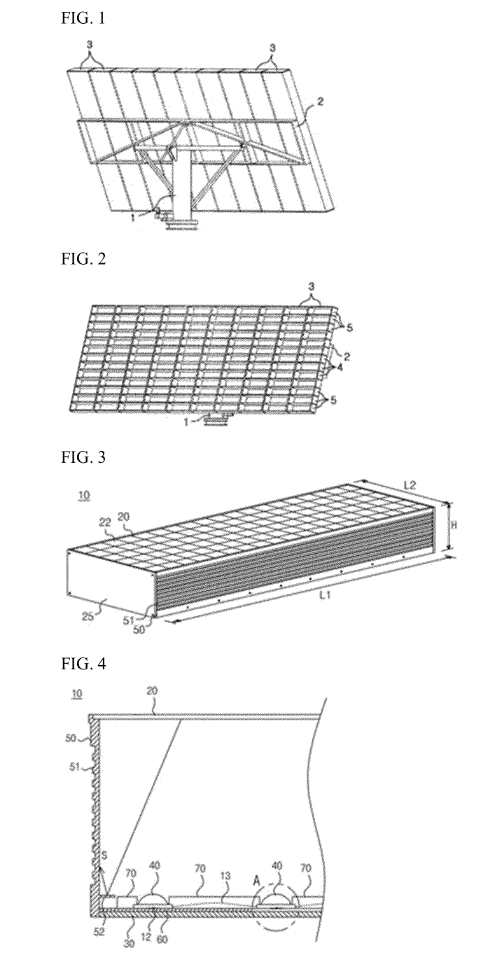

### BEST MODE

Hereinafter, exemplary embodiments of the present invention will be described in detail with reference to the attached drawings.

This invention may, however, be embodied in many different forms, and should not be construed as limited to the embodiments set forth herein. Rather, all changes that fall within the bounds of the present invention, or the equivalence of the bounds, are therefore intended to be embraced by the present invention.

In the drawings, the size of each element, the thickness of lines illustrating the element, etc. may be exaggeratedly expressed in the drawings for clarity of illustration, but due to this, the protective scope of the present invention should not be interpreted narrowly.

In this specification, the relative terms ‘vertical direction’ and ‘horizontal direction’ are just relative terms for use in explaining the relationship between elements based on the orientation indicated in the drawings. The scope of the present invention is not restricted by these terms.

Embodiments of the present invention relate to a concentrating photovoltaic module for easily integrally assembling a heat pipe for dissipation of heat generated from a solar cell with a concentrating photovoltaic module that has comparatively high stiffness and is configured such that manufacture and assembly thereof may be facilitated.

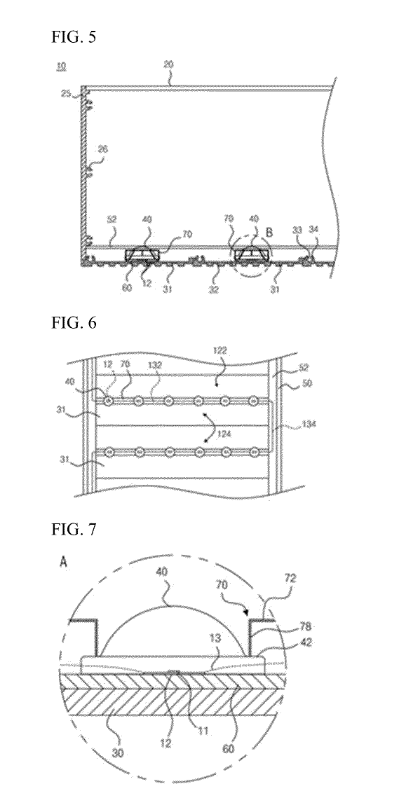

FIG. 3 is a perspective view of a concentrating photovoltaic module 10 according to an embodiment of the present invention. FIG. 4 is a vertical cross-sectional view of the concentrating photovoltaic module 10 of FIG. 3 taken along a horizontal line thereof. FIG. 5 is a vertical cross-sectional view of the concentrating photovoltaic module 10 of FIG. 3 taken along a vertical line thereof.

Referring to FIGS. 3 to 5, the concentrating the photovoltaic module 10 according to this embodiment of the present invention includes a frame including a side plate and a lower plate 30, carriers 12 each provided with a solar cell 11 disposed thereon and spaced apart from each other on the lower plate 30, and a lens plate 20 disposed on the frame and for concentrating sunlight incident thereon on the solar cell 11.

The frame may extend a predetermined length in a longitudinal direction and has comparatively high stiffness. The frame includes the side plate and the lower plate 30 and is configured to be open on an upper side thereof.

The side plate includes a horizontal plate 25 that extends a comparatively small length in a horizontal direction and a vertical plate 50 that extends a greater length than the horizontal plate 25 in a vertical direction. For example, a length L1 of the vertical plate 50 may be about 5 to 10 times a length L2 of the horizontal plate 25. A height H of the vertical plate 50 may be about 1/20 to 1/10 of the length L1.

The frame, that is, the vertical plate 50, the horizontal plate 25, and the lower plate may be integrally manufactured by extrusion molding such that the photovoltaic module 10 according to embodiments of the present invention may easily manufactured and assembled and has comparatively high stiffness. To this end, the overall size of the frame may be achieved via extrusion molding. For example, at present, the height of the vertical plate 50 that is capable of being integrally manufactured by extrusion molding ranges from about 25 cm to about 50 cm, and the length thereof ranges from about 4 m to about 6 m. With regard to the optimized size of the frame in consideration of manufacture and maintenance in stiffness of the frame, the vertical plates 50 that are capable of being integrally manufactured by extrusion molding may have a size that may be integrally manufactured by extrusion molding, in other words, the length of vertical plate 50 may range from about 4 m to about 6 m and the height thereof may range from about 25 cm to about 50 cm. Accordingly, the length of the horizontal plate 25 may range about 1 m to 1.2 in. When the frame has the above-mentioned size, the carriers 12 may be arranged such that six carriers 12 are arranged in the horizontal direction to form a horizontal carrier array, and twenty horizontal arrays are arranged in the vertical direction. Accordingly, a total of about 120 solar cells 11 or more may be provided. However, embodiments of the present invention are not limited thereto. Needless to say, the size of the frame may be changed depending on the purpose of design or the development of the extrusion molding technology.

The vertical plate 50, the horizontal plate 25, and the lower plate that constitute the frame may be formed of aluminum that is light, has comparatively high stiffness, and has high heat conductivity.

The lens plate 20 may be provided on the frame and concentrate incident sunlight on the solar cell 11. The lens plate 20 may include a plurality of pattern portions 22 that concentrate incident sunlight on each of the solar cells 11. The pattern portion 22 may have the same structure as that of a Fresnel lens. That is, the lens plate 20 is configured in such a way that a plurality of Fresnel lens patterned parts is formed in a plate. In addition, the lens plate 20 may be configured with a single plate or a plurality of piece lens plates that are provided on the frame and coupled.

The concentrating the photovoltaic module 10 according to this embodiment of the present invention may further include a plurality of carrier frames 60 provided on the lower plate 30 and including spaced apart from each other by a predetermined interval thereon, a wire 13 connecting the carriers 12 in parallel or series to each other, a wire cover 70 for covering the wire 13, and a secondary optical element (SOE) 40 that is provided between the lens plate 20 and the solar cell 11 and secondarily concentrates, on the solar cell 11, light concentrated by the lens plate 20.

The solar cell 11 may convert solar energy into electric energy. A high efficiency III-V compound semiconductor multi-junction solar cell may be used as the solar cell 11. The carrier 12 may be configured such that the solar cell 11, along with other elements, is mounted to a circuit board. A receiver typically used in this art pertaining to the present invention may be used as the carrier 12. That is, according to embodiments of the present invention, the carrier 12 formed in such a way that the solar cell 11 is provided on the circuit board may be configured in a variety of forms. The term ‘carrier’ may be used as a term including a receiver. The carriers 12 may be spaced apart from each other by a predetermined interval on the lower plate 30. The carrier 12 may be provided with a connector. The carrier 12 may be connected by electrically connecting the connectors using the wire 13 in parallel or series to each other.

The vertical plate 50 that extends in a longitudinal direction and extends in a vertical length to have relatively high stiffness may include a plurality of ribs that protrude to enhance stiffness. The ribs may include at least one of heat dissipation ribs 51 and reflective ribs 52.

The heat dissipation ribs 51 may protrude from an external side surface of the vertical plate 50 to enhance the stiffness of the vertical plate 50 and to simultaneously increase a contact area with the outside, thereby smoothly and externally transmitting and dissipating heat transferred from a closed interior of the frame to the vertical plate 50.

The reflective ribs 52 may protrude from a lower portion of an inner surface of the vertical plate 50 to enhance stiffness of the vertical plate 50 and to simultaneously reflect sunlight off-axis from the lens plate 20, thereby preventing the sunlight S from being incident on elements such as the wire 13. The off-axis sunlight may be generated when sunlight is not vertically incident on the lens plate 20. A main element to be damaged by the off-axis sunlight S may be the wire 13. That is, the reflective ribs 52 may mainly protect the wire 13 along with the wire cover 70.

The heat dissipation ribs 51 and the reflective ribs 52 have constant cross-sections and extend in the vertical direction of the vertical plate 50 such that the vertical plate 50 may be manufactured by extrusion molding. As such, the vertical plates 50 having the above-mentioned cross-section are integrally manufactured by extrusion molding, the manufacture and assembly processes may be facilitated.

A coupling rib 26 for screw-coupling with the vertical plate 50 may protrude on an inner or outer surface of the horizontal plate 25. The coupling rib 26 functions not only to enhance the stiffness of the horizontal plate 25 but also to facilitate the screw-coupling with the vertical plate 50. The coupling rib 26 may have a constant vertical cross-section and extend in the horizontal direction such that the horizontal plates 25 are integrally formed.

The lower plate 30 includes a plurality of lower plate pieces 31 each of which has a predetermined width with respect to the vertical direction and that are arranged in the vertical direction and are coupled to each other. Each of the lower plate pieces 31 is coupled to a lower surface of the longitudinal plate 50 by screws and has a length corresponding to that of the horizontal plate 25.

The lower plate piece 31 may include a coupling rib 34 including a heat dissipation rib 32 that protrude from the lower surface of each of the lower plate pieces 31 and a coupling portion 33 protruding from the upper surface of the lower plate piece 31 and for use in screw-coupling with the vertical plate 50.

The stiffness of the lower plate piece 31 may be enhanced by the heat dissipation ribs 32 and the coupling rib 34. The heat dissipation ribs 32 increase the contact area with the outside such that heat transferred from the closed interior of the frame to the lower plate piece 31 may be smoothly transferred and dissipated to the outside. Furthermore, the coupling hole 35 for use in screw-coupling with the vertical plate 50 is formed in the coupling rib 34, and thus the coupling portion 33 may be easily formed in the lower plate piece 31 formed of a thin board.

In the concentrating the photovoltaic module 10 according to embodiments of the present invention, when the lower plate 30 and the horizontal plate 25 have the aforementioned cross-section in the horizontal direction and the vertical plate 50 has the aforementioned cross-section in the vertical direction, the lower plate 30, the horizontal plate 25, and the vertical plate 50 may be easily assembled. In addition, the lower plate 30 and the horizontal plate 25 have the aforementioned cross-section in the horizontal direction and the vertical plate 50 has the aforementioned cross-section in the vertical direction, which is desirable because the lower plate 30 or the vertical plate 50 may be integrally manufactured through a single extrusion molding process. However, the size of the plate that is capable of being manufactured through a single extrusion molding process is limited, and thus the concentrating solar cell module panel 10 according to embodiments of the present invention is configured such that the vertical plate 50 is integrally manufactured through an extrusion molding process so as to enhance the stiffness of the concentrating the photovoltaic module 10, and the lower plate 30 is formed by vertically arranging the lower plate pieces 31 each having an appropriate width to be manufactured by extrusion molding and then coupling the lower plate pieces 31 to each other, thereby facilitating the manufacture of each plate and the overall assembly process. Furthermore, in this case, the lower plate pieces 31 of the lower plate 30 may be conveniently manufactured in such a way that after a plate is integrally formed by extrusion molding to have a predetermined length, the plate is cut by a desired length.

FIG. 6 is a schematic diagram of a case in which the carriers 12 are arranged on the lower plate of a concentrating photovoltaic module according to an embodiment of the present invention.

Referring to FIG. 6, the carrier 12 may be arranged in such a way that a plurality of carrier 12 are spaced apart from each other by a predetermined interval to form a horizontal array 122 in a horizontal direction and a plurality of horizontal arrays 122 are arranged to form a vertical array 124 in a vertical direction. The carriers 12 are connected each other by the wires 13.

For example, the carriers 12 forming each horizontal array 122 may be connected to each other by horizontal connection wires 132. With regard to the vertical array 124, the vertical arrays 124 are connected to each other in such a way that the carrier 12 disposed on an end of each horizontal array 122 is connected to the carrier 12 disposed on a corresponding end of the adjacent horizontal array 122 by a vertical connection wires 132. In this case, the horizontal connection wires 132 may be protected by the wire cover 70. However, the vertical connection wires 132 is disposed at one side of the concentrating photovoltaic module 10, and thus it is difficult to couple the vertical connection wires 132 with the wire cover 70 due to the assembly structure of the wire cover 70. Accordingly, a separate protection method for protection of the vertical connection wires 132 is required. In the concentrating photovoltaic module 10 according to embodiments of the present invention, the reflective ribs 52 that protrude inward the vertical plate 50 functions not only to enhance the stiffness of the vertical plate 50 but also to protect the vertical connection wires 132.

The carrier frames 60 may be used to facilitate coupling of the plurality of carriers 12. that are arranged in a horizontal direction to the lower plate 30, may be formed with various shapes, and may include a heat pipe therein for dissipation of heat generated from the solar cell 11. Likewise, when the heat pipe is installed in the carrier frames 60, the heat pipe may be easily and integrally assembled with the concentrating photovoltaic module 10 and also an effect of heat dissipation may be maximized, which will be described below in detail.

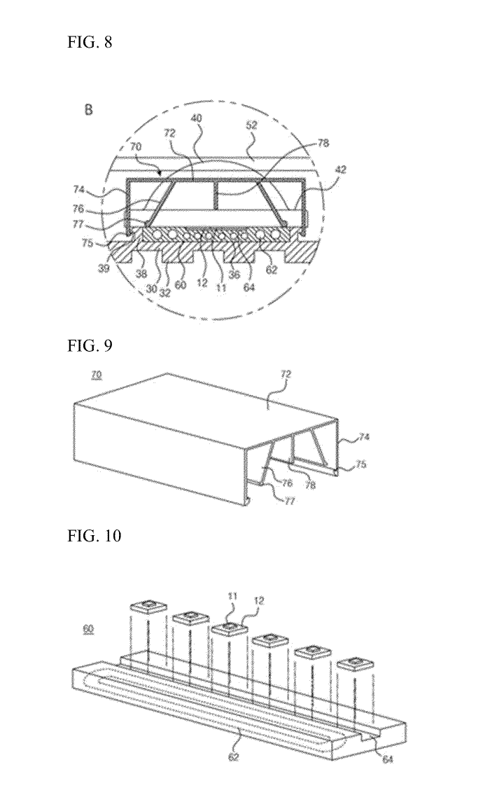

FIG. 7 is an enlarged view of a portion ‘A’ of FIG. 4. FIG. 8 is an enlarged view of a portion ‘B’ of FIG. 5. FIG. 9 is a perspective view of the wire cover 70 according to an embodiment of the present invention. FIG. 10 is a perspective view of the carrier frame 60 according to an embodiment of the present invention.

Referring to FIGS. 7 to 10, the carrier frame 60 may be couple onto the lower plate 30 by the wire cover 70.

In order to effectively dissipate heat generated from the solar cell 11, the carrier frames 60 may be formed of aluminum that is light, has comparatively high stiffness, and has high heat conductivity, like the lower plate 30. Likewise, when the carrier frames 60 is formed of the same material as the lower plate 30, there is a need for a separate component for coupling the carrier frames 60 onto the lower plate 30. However, if the carrier frame 60 is fixedly coupled onto the lower plate 30 using a separate screw, and so on, there is a problem in that an overall structure is complex and an assembly procedure is also complex.

Accordingly, the photovoltaic module 10 according to embodiments of the present invention may be configured in such a way that the carrier frame 60 is coupled onto lower plate 30 together when the wire cover 70 for protection of the wire 13 is coupled onto the lower plate 30. That is, the wire cover 70 may be disposed on the lower plate 30 so as to cover the wire 13 and may fixedly couple the carrier frames 60 onto the lower plate 30.

In detail, the wire cover 70 may include an upper plate 72 for covering the wire 13, a first leg portion 74 that extends downward from on one side of the upper plate 72 (e.g., an end of the upper plate 72) and is coupled to the lower plate 30, and a second leg portion 76 that extends downward from another side of the upper plate 72 (e.g., a point spaced apart from the end of the upper plate 72 by a predetermined distance) so as to be positioned inside the first leg portion 74.

In addition, when the first leg portion 74 is coupled to the lower plate 30, the second leg portion 76 may be configured to compress the first leg portion 74 onto the lower plate 30. For example, the second leg portion 76 may be formed with a shorter length than that of the first leg portion 74 so as to compress the carrier frames 60 when the first leg portion 74 is coupled to the lower plate 30. The second leg portion 76 may be inclined at a predetermined angle so as to have predetermined elastic force in a direction for compressing the carrier frames 60. One pair of second leg portions 76 may be configured to face each other and formed to be away from each other downward. In this case, the second leg portion 76 may have higher elastic force in the direction for compressing the carrier frames 60 and thus may more strongly fix the carrier frame 60 when the first leg portion 74 is coupled to the lower plate 30. In addition, an end portion 77 with a circular cross-section may be formed at an end of the second leg portion 76 so as to smoothly compress the carrier frame 60.

As described above, the lower plate 30 may include the plurality of lower plate pieces 31 that are arranged in a vertical direction, an accommodation portion 36 for accommodation of the carrier frame 60 may be formed in a longitudinal direction on the lower plate pieces 31, and a coupling protrusion 38 to which the wire cover 70 is to be coupled may protrude outside the accommodation portion 36.

The carrier frame 60 may extend in a horizontal direction so as to be accommodated in the accommodation portion 36 that extends in the horizontal direction, and at least two carriers 12 of a plurality of carriers that are arranged in a horizontal direction may be disposed on the carrier frame 60. The carrier 12 with the solar cell 11 disposed thereon may be attached to the carrier frame 60 by a sealing member such as silicon and so on.

A stumbling projection 39 that externally extend may be formed at an end of the coupling protrusion 38, and a stumbling portion 75 stumbled by the stumbling projection 39 may be formed at one side of the first leg portion 74 (e.g., an inner portion of an end of the first leg portion 74) of the wire cover 70.

Accordingly, the upper plate 72 of the wire cover 70 may cover and protect the wire 13 (e.g., the horizontal connection wires 132) for connection of the plurality of carriers 12 that are spaced apart from each other by a predetermined interval in a horizontal direction, the stumbling portion 75 of the first leg portion 74 may be stumbled by the stumbling projection 39 such that the wire cover 70 is coupled to the lower plate pieces 31, and the second leg portion 76 may compress the carrier frames 60 when the stumbling portion 75 is stumbled by the stumbling projection 39.

The carrier frame 60 may include a heat pipe 62 disposed therein.

The heat pipe 62 may have a closed-loop shape, accommodate a refrigerant therein, and include an evaporation portion for evaporating the refrigerant by heat generated from the solar cell 11 and a condensation portion for condensing the evaporated refrigerant. However, the detailed configuration of the heat pipe 62 may be easily understood by one of ordinary skilled in the art to which embodiments of the present invention pertain, and thus a detailed description thereof will be omitted here, and the embodiments of the present invention are not limited by the detailed configuration of the heat pipe 62.

The carrier frame 60 may extend in a longitudinal direction. In addition, an accommodation groove 64 may extend in a longitudinal direction on the carrier frame 60 such that the plurality of carriers 12 is spaced apart from each other in a line by a predetermined interval.

Accordingly, in the concentrating photovoltaic module 10 according to embodiments of the present invention, only the carrier frame 60 may be fixed using the wire cover 70 without separately fixing the plurality of carriers 12, and thus overall assembly processes may be very simply and easily performed.

In addition, since the heat pipe 62 for dissipation of heat generated from the solar cell 11 is installed in the carrier frames 60, a separate device for heat dissipation is not required and does not have to be separately assembled, and thus the heat pipe 62 for dissipation of heat generated from a solar cell may be easily and integrally assembled with the concentrating the photovoltaic module 10.

As described above, the concentrating the photovoltaic module 10 according to embodiments of the present invention may include the carrier frame 60 so as to easily couple the plurality of carriers 12 that are arranged in a horizontal direction to the lower plate 30, and the wire cover 70 so as to easily couple the carrier frames 60 to the lower plate 30.

In addition, the concentrating the photovoltaic module 10 according to embodiments of the present invention may include the heat pipe 62 disposed in the carrier frame 60 that is easily coupled to the lower plate 30 and for dissipation of heat generated from the solar cell 11, and thus the heat pipe 62 may be easily and integrally assembled with the concentrating the photovoltaic module 10. In addition, when the heat pipe 62 may be disposed in the carrier frame 60, a heat dissipation effect may be maximized.

Since the carrier frame 60 is coupled to the lower plate 30 so as to directly contact the lower plate 30 in a horizontal direction, that is, in a longitudinal direction of the lower plate 30 on the lower plate 30 and includes the carriers 12 that are arranged in a horizontal direction on the carrier frames 60, when the carrier frame 60 includes the heat pipe 62 disposed therein, heat generated from the plurality of carriers 12 that are arranged in a horizontal direction may be quickly and uniformly transferred in a horizontal direction through the heat pipe 62 before being transferred into the concentrating the photovoltaic module 10, and the heat that is uniformly transferred in the horizontal direction may be externally dissipated through the lower plate 30. Likewise, the heat transferred to the lower plate 30 may be more effectively and externally dissipated by heat dissipation protrusions 32 formed below the lower plate 30.

The wire cover 70 may be configured to fix a secondary optical element 40 upon being coupled to the lower plate 30. To this end, the wire cover 70 may further include a third leg portion 78 extending downward from one side of the upper plate 72 and for compressing a flange 42 of the secondary optical element 40 when the first leg portion 74 is coupled to the lower plate 30. The third leg portion 78 may be formed with a shorter length the first leg portion 74 and/or the second leg portion 76 so as to compress the flange 42 of the secondary optical element 40 when the stumbling portion 75 of the first leg portion 74 is stumbled by the stumbling projection 39.

In the concentrating the photovoltaic module 10 according to embodiments of the present invention, the secondary optical element 40 may be formed in the form of a lens or may also be formed in the form of a reflection-coated reflector. Embodiments of the present invention are not limited by a detailed shape of the secondary optical element 40.

In addition, like the horizontal plate 25 and the vertical plate 50, the lower plate pieces 31 may be integrally formed by extrusion molding. To this end, the heat dissipation ribs 32, the coupling rib 34, the accommodation portion 36, and the coupling protrusion 38 may have constant cross-sections and extend in a horizontal direction. Accordingly, the lower plate pieces 31 may be easily manufactured and assembled in such a way that after a plate is integrally formed by extrusion molding to have a predetermined length, the plate is cut and assembled by a desired length.

As described above, the present invention relates to a concentrating photovoltaic module for easily integrally assembling a heat pipe for dissipation of heat generated from a solar cell with the concentrating photovoltaic module that has sufficient stiffness is easily manufactured and assembled. The present invention may be embodied in a variety of forms. Therefore, the present invention is not limited to the embodiments disclosed in this specification. All changes that fall within the bounds of the present invention, or the equivalence of the bounds, should be understood to be embraced by the present invention.

1-14. (canceled)

15. A concentrating photovoltaic module comprising:
a frame comprising a side plate and a lower plate;
carriers each provided with a solar cell;
a lens plate disposed on the frame and for concentrating sunlight incident thereon on the solar cell;
a carrier frame disposed on the lower frame and comprising the plurality of carriers spaced apart from each other by a predetermined interval; and
a wire for connection of the carriers,
wherein the carrier frame comprises a heat pipe disposed therein.

16. The concentrating photovoltaic module according to claim 15, wherein:
the carrier frame extends in a longitudinal direction;
the carriers are arranged in a longitudinal direction to be spaced apart from each other in a line by a predetermined interval on the carrier frame; and
heat dissipation ribs protrude below the lower plate.

17. The concentrating photovoltaic module according to claim 15, wherein:
the lower plate comprises a plurality of lower plate pieces arranged in a vertical direction, and an accommodation portion for accommodation of the carrier frame is formed in a longitudinal direction on the lower plate pieces; and
the carrier frame extend in a horizontal direction so as to be accommodated in the accommodation portion, and an accommodation groove extends in a longitudinal direction on the carrier frame such that at least two carriers of a plurality of carries arranged in a horizontal direction among the carriers are spaced apart from each other by a predetermined interval.

18. The concentrating photovoltaic module according to claim 15, wherein:
the side plate comprises a horizontal plate and a vertical plate extending a greater length than the horizontal plate, and the lower plate comprises a plurality of lower plate pieces arranged and coupled in a vertical direction and each coupled to the vertical plate by screws; and
the carrier frame extends in a longitudinal direction of the lower plate pieces, the carriers are arranged in the longitudinal direction to be spaced apart from each other in a line on the carrier frame, and heat dissipation ribs protrude below the lower plate pieces.

19. The concentrating photovoltaic module according to claim 15, wherein:
the side plate comprises a horizontal plate and a vertical plate extending a greater length than the horizontal plate, and the lower plate comprises a plurality of lower plate pieces arranged and coupled in a vertical direction and each coupled to the vertical plate by screws;
the lower plate pieces comprise heat dissipation ribs protruding therebelow and an accommodation portion extending thereabove in a longitudinal direction and for accommodation the carrier frame; and
the carrier frame extends in a longitudinal direction of the lower plate pieces, and an accommodation groove extends in a longitudinal direction on the carrier frame such that the carriers are arranged to be spaced apart from each other in a line by a predetermined interval.

20. The concentrating photovoltaic module according to claim 15, further comprising a wire cover coupled to the lower plate while fixing the carrier frame.

21. The concentrating photovoltaic module according to claim 20, wherein the wire cover comprises:
a first leg portion extending downward from one side of the upper plate and coupled to the lower plate; and
a second leg portion extending downward from another side of the upper plate so as to be positioned inside the first leg portion and for compressing the carrier frame when the first leg portion is coupled to the lower plate.

22. The concentrating photovoltaic module according to claim 21, wherein one pair of second leg portions face each other and is formed to be away from each other downward.

23. The concentrating photovoltaic module according to claim 21, wherein a stumbling portion stumbled by a stumbling projection formed on the lower plate is formed at one side of the first leg portion.

24. The concentrating photovoltaic module according to claim 21, further comprising a secondary optical element for secondarily concentrating light concentrated from the lens plate on the solar cell,
wherein the wire cover further comprises a third leg portion for compressing a flange of the secondary optical element when the first leg portion extends downward from one side of the upper plate and is coupled to the lower plate.
